(19) United States
(12) Patent Application Publication
(10) Pub. No.: US 2003/0016072 A1
(43) Pub. Date: Jan. 23, 2003

(54) Mosfet-based analog switches

(76) Inventor: Shankar Ramakrishnan, Campbell, CA (US)

Correspondence Address: STEPHEN R. SCHAEFER, Fish & Richardson P.C., P.A., Suite 3300, 60 South Sixth Street, Minneapolis, MN, 55402, US

(21) Appl. No.: 09/908,469

(22) Filed: Jul. 18, 2001

(51) Int. Cl. H03K 17/687

(52) U.S. Cl. 327/434

(57) ABSTRACT

An analog switch includes a MOSFET that serves as a switching transistor through which the signal received at an input terminal of the analog switch passes to an output terminal of the analog switch. A resistor is coupled to the gate of the switching transistor to prevent the discharge of gate capacitance when a control signal is activating the switching transistor in an ON state. A second MOSFET has its source and drain terminals coupled across the gate and substrate of the switching transistor. The second MOSFET is activated to an ON state to provide low-impedance driving of the switching transistor when the control signal is driving the switching transistor to an OFF state. The switching MOSFET and the second MOSFET may be NMOS devices in some embodiments, while in other embodiments, PMOS devices.

### TECHNICAL FIELD

The invention relates to analog switches, and in particular metal-oxide semiconductor (MOS) analog switches.

### BACKGROUND

Analog switches are fundamental building blocks in analog circuit design. An analog switch is turned ON and OFF by-low voltage control signal. When the analog switch is in the ON state, an analog electrical signal is conducted from an input terminal, through a transistor switch, to an output terminal. Analog switches have many applications, including low-voltage applications such as audio and video signal routing, gain selection, and many others, and high-voltage applications such as ultrasound imaging, digital subscriber loop applications, and many others.

Today's analog switches typically employ metal-oxide semiconductor field-effect transistors (MOSFETs) as the transistor switch through which the electrical signal conducts. The MOSFET switch may be an n-channel device (NMOS transistor), a p-channel device (PMOS transistor), or a pair of NMOS and PMOS transistors which enables current to be conducted through the analog switch in either direction. NMOS transistors have a smaller die size than PMOS transistors. The smaller die size makes NMOS transistors less capacitive, and thus NMOS transistors enable faster switching speeds, which is necessary in many applications.

A prior art analog switch 10, shown in FIG. 1, includes an NMOS switch transistor N1 with its drain connected to an input terminal IN, its source connected to an output terminal OUT, and its gate controlled by a control signal CNTL. When the control terminal CNTL is HIGH, switch transistor N1 is turned ON, thus switching the signal received at the input terminal IN to the output terminal OUT.

To achieve acceptable “flatness” (that is, a constant on-resistance) for AC applications when using an NMOS transistor, a large resistor R1 is typically put in series with the switch transistor N1 gate, as shown in FIG. 1. In the ON state, the series resistor R1 prevents the discharge of the capacitive charge on the gate of the switching transistor N1, and thus holds the gate-to-source voltage Vgs of switch transistor N1 constant even under large signal swing conditions.

In many applications, the NMOS switching transistor N1's gate cannot be driven in the OFF state by high impedance, but instead must be driven by a low impedance to minimize the gate voltage swing, which follows the swing of the signal received at input terminal IN. Minimizing the gate voltage swing may be necessary, especially in high-voltage applications, to obtain high off-isolation and prevent the transistor switch from turning ON when it should not turn ON. To obtain the needed off-isolation, the prior art analog switch 10 in FIG. 1 includes a second NMOS transistor N2, which is activated when N1 is not being activated. The gate of switching transistor N1 is thus switched through N2 to the negative supply V- when the switching transistor Ni is in the OFF state.

The prior art analog switch design shown in FIG. 1 has drawbacks. First, because of the charge on the gate of switching transistor N1, the second transistor N2 is expected to see drain-to-source voltages (Vds) of at least 1.5 times the total supply voltage. In high-voltage applications such as ultrasound probe switching where the total supply voltage may be 220 volts or even more, there may not be sufficient breakdown Vds headroom to accommodate the levels of Vds that could be seen at N2. Another drawback of the analog switch design of FIG. 1 is that the drain capacitance of N2 loads the gate charge of N1 causing signal induced Vgs modulation of N1 that increases distortion.

### SUMMARY

The invention overcomes limitations in prior art analog switches. The analog switch includes a MOSFET that serves as a switching transistor through which the signal received at an input terminal of the analog switch passes to an output terminal of the analog switch. A resistor is coupled to the gate of the switching transistor to prevent the discharge of gate capacitance when a control signal is activating the switching transistor in an ON state. A second MOSFET has its source and drain terminals coupled across the gate and substrate of the switching transistor. The second MOSFET is activated to an ON state to provide low-impedance driving of the switching transistor when the control signal is driving the switching transistor to an OFF state. The switching MOSFET and the second MOSFET may be NMOS devices in some embodiments, while in other embodiments, PMOS devices.

In various embodiments, the analog switch may include an additional switch that couples the substrate of the switching transistor and the source of the second MOSFET to either a negative supply voltage (in NMOS embodiments) or a positive supply (in PMOS embodiments) when the second MOSFET is activated to an ON state. The analog switch may also include yet another switch that drives the second MOSFET OFF when the control signal is activating the switching transistor in an ON state, and a switch that that drives the second MOSFET ON when the control signal is activating the switching transistor in an OFF state. Also, the analog switch may include a switch that couples the signal received at the input terminal to the substrate of the switching transistor when the switching transistor is being driven to an ON state.

The invention offers one or more of the following advantages. Because the second MOSFET is connected between the gate and substrate of the switching transistor, and because of the charge stored on the switching transistor, the second MOSFET sees a relatively constant voltage regardless of the voltage swing. This means that the drain-to-source voltage (Vds) of the second MOSFET will never exceed the supply voltage, thus conserving breakdown Vds headroom which is especially important in high-voltage applications. Also, because the drain capacitance of the second MOSFET is parallel to the gate-channel capacitance of the switching transistor, there is no signal-induced gate drive modulation of the switching transistor. Therefore, distortion is minimized and linearity of the on-resistance for the switching transistor is not compromised.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a schematic diagram of a prior art analog switch.

FIG. 2 is a schematic diagram of an analog switch in accordance with the invention.

FIGS. 3A and 3B are schematic diagrams of circuitry that may be added to the analog switch of FIG. 2.

FIG. 4 is a schematic diagram of an alternative embodiment of an analog switch in accordance with the invention.

### DETAILED DESCRIPTION

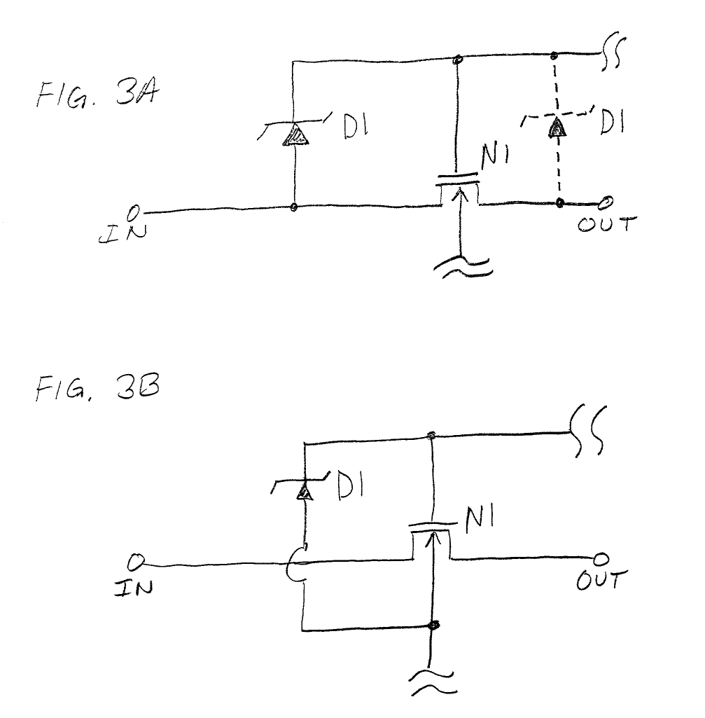

An analog switch 20 in accordance with the invention, shown in FIG. 2, includes an NMOS switch transistor N1 with its drain connected to an input terminal IN, its source connected to an output terminal OUT, and its gate controlled by a control signal CNTL. When control signal CNTL is HIGH, switch transistor N1 is turned ON, thus switching the signal received at the input terminal IN to the output terminal OUT.

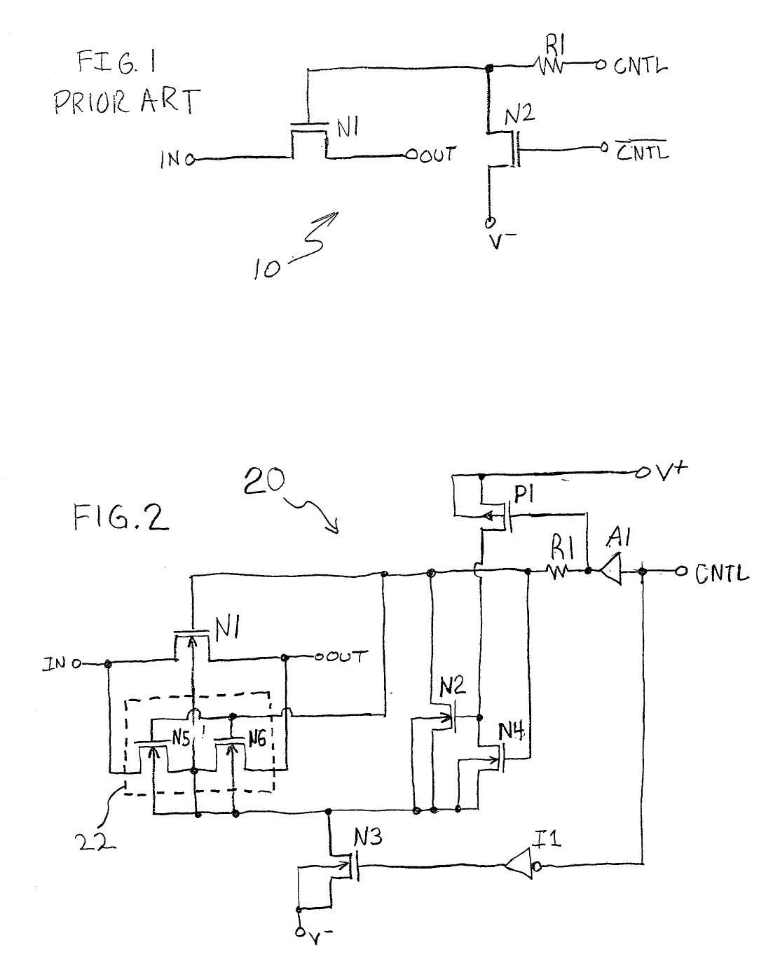

A large resistor R1 is in series with the switch transistor N1 gate and the control signal CNTL, as was the case in the prior art switch 10 shown in FIG. 1. Thus, during the time that the control signal is HIGH, the series resistor R1 prevents the discharge of the capacitive charge on the gate of the switch transistor N1, and thus holds the gate-to-source voltage Vgs of switch transistor N1 constant even under large signal swing conditions.

To obtain the necessary off-isolation when the switch transistor N1 is in the OFF state, NMOS transistor N2 in combination with NMOS transistor N3 switches the gate of N1 to the negative supply V⁻. The drain of N2 is connected to the gate of switch transistor N1. The source of N2 is connected to the substrate of switch N1 and to the substrate of N2. N2 is thus connected between the gate and substrate of N1, which offers benefits that will be described later. Owing to the functioning of PMOS transistor P1 and NMOS transistor N4, whose operation will be described later, N2 is ON when the control signal CNTL is LOW and N1 OFF. N3 has its drain connected to the source of N2 and to the substrates of both N2 and N1. N3 receives at its gate the control signal CNTL after having been inverted by inverter I1, and thus N3 switches the substrates of N2 and N1 to the negative supply V⁻ when the control signal CNTL is LOW. The connection of the N1 substrate to the negative supply V⁻ reverse biases Ni.

NMOS transistor N4 serves to drive N2 OFF when the control signal CNTL is HIGH and thus switch transistor N1 is ON. PMOS transistor P1 serves to drive N2 ON when the control signal CNTL is LOW and thus switch transistor N1 is OFF. NMOS transistor N4 receives the control signal CNTL at its gate. The drain of N4 is connected to both the gate of N2 and to the drain of PMOS transistor P1. The source of N4 is connected to the substrate of both N1 and N2, as well as to the substrate of N4. The control signal CNTL being HIGH activates N4 to the ON state and also turns P1 OFF, which shorts the gate of N2 to its source, thus ensuring that N2 is OFF when the control signal CNTL is HIGH. PMOS transistor P1 also receives the control signal CNTL, via buffer A1, at P1's gate. The source of P1 is connected to positive supply voltage V⁺. The source of P1 is also connected to P1's substrate. Thus, CNTL being LOW turns P1 on, which turns N2 OFF.

Circuitry 22, which includes NMOS transistors N5 and N6, switches the substrate of switch transistor N1 to the signal received at input terminal IN when N1 is ON, and in so doing minimizes the body effect of N1. The drain of N5 is connected to the drain of N1, the source of N5 to the drain of N6, and the source of N6 to the output terminal OUT. The substrates of N5 and N6 are common and connected to the substrate of N1 and to the source and substrate of N2. N5 and N6 both receive the control signal CNTL at their gates. Therefore, both N5 and N6 are turned ON when the control signal CNTL is HIGH. The substrate of N1 is therefore tied to the signal level received at N1's drain. This minimizes the body effect. It also should be noted that during the time the input signal at terminal IN is tied to the N1 substrate, N3 is OFF and thus the N1 substrate is not also connected to the negative supply.

When the switch 20 is ON, the substrate of N1 is at the signal level due to the operation of circuitry 22, which minimizes the body effect. Also when the switch 20 is ON, N2 is OFF. Because N2 is connected between the gate and substrate of N1, and because of the charge stored on the gate of N1, N2 sees a relatively constant voltage regardless of the signal swing. This means that the Vds of N2 will never exceed the supply voltage. This aspect of the invention thus conserves breakdown Vds headroom, which is especially important in high-voltage applications. Also, because the drain capacitance of N2 is parallel to the gate-channel capacitance of N1, there is no signal-induced gate drive modulation of N1. Therefore, a design in accordance with the invention does not compromise the linearity of the on-resistance of the switch transistor Ni. When the switch 20 is OFF, N2 and N3 are ON. The impedance seen by the gate of switch transistor N1 is the sum of the impedances of N2 and N3. These two devices, that is, N2 and N3, may be made as large as possible to achieve the required off-isolation.

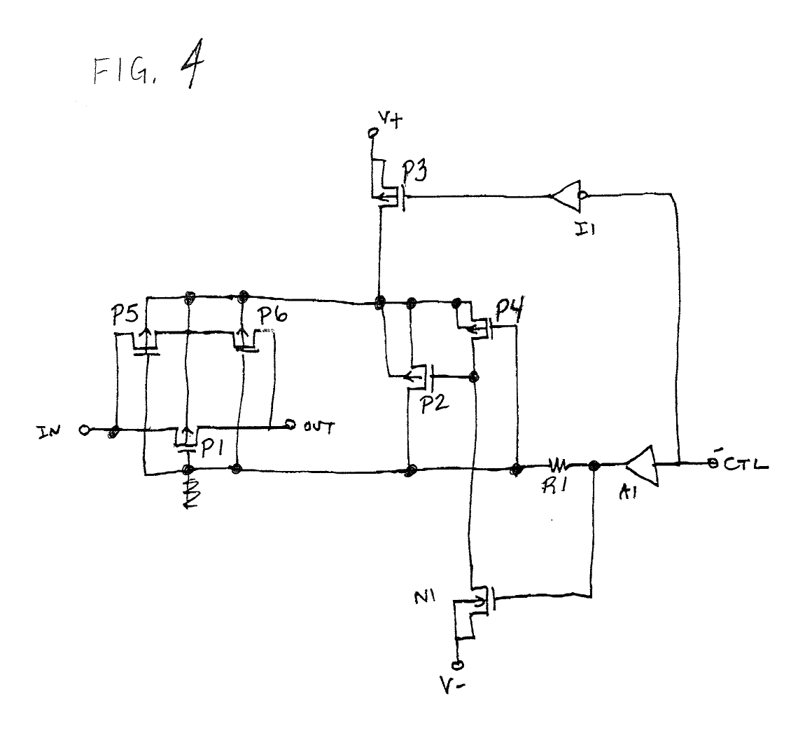

In some embodiments, the semiconductor manufacture process employed may limit by the level of gate-to-source voltage Vgs that N1 can sustain. In these cases it may be necessary to ensure that the gate-to-source voltage Vgs of N1 does not exceed a prescribed limit. To ensure this, a voltage clamp D1 may be connected between the gate and drain (input terminal IN) of N1, as shown in FIG. 3A. The voltage clamp D1 may alternatively be connected between the gate and source of N1 (shown in FIG. 3A by dashed lines). Also, circuit 22 connects the N1 substrate to the input terminal IN when N1 is ON, yet another alternative is to connect the voltage clamp D1 between the gate and substrate of N1, as shown in FIG. 3B. In the embodiments of FIG. 3A and 3B, the voltage clamp is a zener diode D1, although those skilled in the art will recognize that other configurations of voltage clamps may be used. Also, combination of one or more of the above may be used.

FIG. 4 shows an alternative embodiment of the invention where the switch transistor is a PMOS transistor P1 instead of the NMOS transistor N1 in the FIG. 2 embodiment. Also, the NMOS transistors N2-N6 of the FIG. 2 embodiment are replaced with PMOS transistors P2-P6 in the FIG. 4 embodiment, and the PMOS transistor P1 of FIG. 2 is replaced with the NMOS transistor N1 of FIG. 4. The PMOS embodiment of FIG. 4 operates similarly to the NMOS embodiment of FIG. 2. PMOS transistor P2 in combination with PMOS transistor P3 switches the gate of P1 to the positive supply V⁺. PMOS transistor P4 serves to drive P2 OFF when the control signal is LOW and thus P1 is ON, while NMOS transistor N1 serves to drive P2 ON when the control signal is HIGH and thus switch transistor P1 is OFF. PMOS transistors P5 and P6 switch the substrate of switch transistor P1 to the signal received at the input terminal IN when P1 is ON, and in so doing minimizes the body effect of P1. P2 is connected between the gate and substrate of P1, and thus, because of the charge stored on the gate of P1, P2 sees a relatively constant voltage regardless of the signal swing. Also, the drain capacitance of P2 is parallel to the gate-channel capacitance of P1, and so there is no signal-induced gate drive modulation of P1. Therefore, as with the NMOS embodiment of FIG. 2, a PMOS embodiment of the type shown in FIG. 4 does not compromise the linearity of the on-resistance of the switch transistor P1.

While certain exemplary embodiments have been described and shown in the accompanying drawings, it is to be understood that such embodiments were merely illustrative of and not restrictive on the broad invention, and that this invention not be limited to the specific constructions and arrangements shown and described, because various other modifications may occur to those of ordinary skill in the art. For example, in the switch 20 of FIG. 2, switch transistor N1 could be eliminated and NMOS transistors N5 and N6 may then serve as the switch transistor. This is commonly done with double diffusion MOS (DMOS) embodiments of analog switches. In FIG. 2, circuitry other than the PMOS transistor P1 and NMOS transistor N4 could be used to turn ON NMOS transistor N2. Other circuitry may be used as circuitry 22 to switch the signal to the N1 substrate.

What is claimed is:

1. An analog switch that switches, under the control of a control signal, a signal received at an input terminal to an output terminal, the analog switch comprising:
a first MOSFET having a drain coupled to one of the input and output terminals, a source coupled to the other of the input and output terminals, a gate that receives the control signal, and a substrate terminal, the first MOSFET passing the signal received at the input terminal to the output terminal when the control signal is activating the first MOSFET in an ON state;
a resistor coupled to the gate of the first MOSFET to prevent the discharge of gate capacitance when the control signal is activating the first MOSFET in the ON state;
a second MOSFET having source and drain terminals coupled across to the gate and substrate of the first MOSFET, the second MOSFET being activated to an ON state to provide low-impedance driving of the first MOSFET gate when the control signal is driving the first MOSFET to an OFF state.

2. The analog switch of claim 1, wherein the first and second MOSFETs comprise NMOS transistors.

3. The analog switch of claim 1, wherein the first and second MOSFETs comprise PMOS transistors.

4. The analog switch of claim 1, further comprising a voltage clamp connected between the gate of the first MOSFET and the input terminal.

5. The analog switch of claim 4, wherein the voltage clamp comprises a zener diode.

6. The analog switch of claim 1, further comprising a voltage clamp connected between the gate and the substrate of the first MOSFET.

7. The analog switch of claim 6, wherein the voltage clamp comprises a zener diode.

8. An analog switch that switches, under the control of a control signal, a signal received at an input terminal to an output terminal, the analog switch comprising:
a first NMOS transistor having a drain coupled to the input terminal, a source coupled to the output terminal, a gate that receives the control signal, and a substrate terminal, the first NMOS transistor passing the signal received at the input terminal to the output terminal when the control signal is activating the NMOS transistor in an ON state;
a resistor coupled to the gate of the first NMOS transistor to prevent the discharge of gate capacitance when the control signal is activating the first NMOS transistor in the ON state;
a second NMOS transistor having a drain coupled to the gate of the first NMOS transistor and a source coupled to the substrate of the first NMOS transistor, the second NMOS transistor being activated to an ON state to provide low-impedance driving of the first NMOS transistor gate when the control signal is driving the first NMOS transistor to an OFF state.

9. The analog switch of claim 8, further comprising a first switch that couples the substrate of the first NMOS transistor and the source of the second NMOS transistor to a negative supply voltage when the second NMOS transistor is activated to an ON state.

10. The analog switch of claim 9, wherein the first switch comprises a third NMOS transistor having a drain coupled to the substrate of the first NMOS transistor and the source of the second NMOS transistor, a source coupled to a negative supply voltage, and a gate that receives the control signal after it has been inverted.

11. The analog switch of claim 8, further comprising a second switch that drives the second NMOS transistor OFF when the control signal is activating the first NMOS transistor in an ON state.

12. The analog switch of claim 11, wherein the second switch comprises a fourth NMOS transistor whose drain is coupled to the gate of the second NMOS transistor, whose gate is coupled to the gate of the first NMOS transistor, and whose source is coupled to the source of the second NMOS transistor.

13. The analog switch of claim 8, further comprising a third switch that drives the second NMOS transistor in an ON state when the control signal is activating the first NMOS transistor in an OFF state.

14. The analog switch of claim 13, wherein the third switch comprises a PMOS transistor whose gate receives the control signal, whose drain is connected to a positive supply, and whose source is coupled to the gate of the second NMOS transistor.

15. The analog switch of claim 12, further comprising a third switch that drives the second NMOS transistor in an ON state when the control signal is activating the first NMOS transistor in an OFF state.

16. The analog switch of claim 15, wherein the third switch comprises a PMOS transistor whose gate receives the control signal, whose drain is connected to a positive supply, and whose source is coupled to the gate of the second NMOS transistor.

17. The analog switch of claim 8, further comprising a fourth switch that couples the signal received at the input and output terminals to the substrate of the first NMOS transistor when the first NMOS transistor is being driven to an ON state.

18. The analog switch of claim 17, wherein the fourth switch comprises a fifth NMOS transistor and a sixth NMOS transistor, wherein:
the gates of the fifth and the sixth transistors are driven by the same control signal that drives the gate of the first NMOS transistor;
the drain of the fifth NMOS transistor is coupled to the input terminal, the source of the fifth NMOS transistor is coupled to the drain of the sixth NMOS transistor and also to the substrate of the first NMOS transistor; and
the source of the sixth transistor is coupled to the output terminal.

19. The analog switch of claim 9, further comprising a fourth switch that couples the signal received at the input terminal to the substrate of the first NMOS transistor when the first NMOS transistor is being driven to an ON state.

20. The analog switch of claim 19, wherein the fourth switch comprises a fifth NMOS transistor and a sixth NMOS transistor, wherein:
the gates of the fifth and the sixth transistors are driven by the same control signal that drives the gate of the first NMOS transistor;
the drain of the fifth NMOS transistor is coupled to the input terminal, the source of the fifty NMOS transistor is coupled to the drain of the sixth NMOS transistor and also to the substrate of the first NMOS transistor; and
the source of the sixth transistor is coupled to the output terminal.

21. The analog switch of claim 8, further comprising a voltage clamp connected between the gate of the first NMOS transistor and the input terminal.

22. The analog switch of claim 21, wherein the voltage clamp comprises a zener diode.

23. The analog switch of claim 8, further comprising a voltage clamp connected between the gate and the substrate of the first NMOS transistor.

24. The analog switch of claim 23, wherein the voltage clamp comprises a zener diode.

25. The analog switch of claim 8, further comprising a voltage clamp connected between the gate of the first NMOS transistor and the output terminal.

26. The analog switch of claim 25, wherein the voltage clamp comprises a zener diode.

27. The analog switch of claim 8, wherein the first NMOS transistor consists of a fifth NMOS transistor and a sixth NMOS transistor, wherein:
the gates of the fifth and the sixth transistors are both driven by the control signal;
the drain of the fifth NMOS transistor is coupled to the input terminal, and the source of the fifth NMOS transistor is coupled to the drain of the sixth NMOS transistor;
the source of the sixth transistor is coupled to the output terminal; and the substrates of the fifth and sixth transistors are coupled to the source of the second NMOS transistor.

28. An analog switch that switches, under the control of a control signal, a signal received at an input terminal to an output terminal, the analog switch comprising:
a first PMOS transistor having a source coupled to the input terminal, a drain coupled to the output terminal, a gate that receives the control signal, and a substrate terminal, the first PMOS transistor passing the signal received at the input terminal to the output terminal when the control signal is activating the PMOS transistor in an ON state;
a resistor coupled to the gate of the first PMOS transistor to prevent the discharge of gate capacitance when the control signal is activating the first PMOS transistor in the ON state;
a second PMOS transistor having a drain coupled to the gate of the first PMOS transistor and a source coupled to the substrate of the first PMOS transistor, the second PMOS transistor being activated to an ON state to provide low-impedance driving of the first PMOS transistor gate when the control signal is driving the first PMOS transistor to an OFF state.

29. The analog switch of claim 28, further comprising a first switch that couples the substrate of the first PMOS transistor and the source of the second PMOS transistor to a positive supply voltage when the second PMOS transistor is activated to an ON state.

30. The analog switch of claim 29, wherein the first switch comprises a third PMOS transistor having a drain coupled to the substrate of the first PMOS transistor and the source of the second PMOS transistor, a source coupled to a positive supply voltage, and a gate that receives the control signal after it has been inverted.

31. The analog switch of claim 28, further comprising a second switch that drives the second PMOS transistor OFF when the control signal is activating the first PMOS transistor in an ON state.

32. The analog switch of claim 31, wherein the second switch comprises a fourth PMOS transistor whose drain is coupled to the gate of the second PMOS transistor, whose gate is coupled to the gate of the first PMOS transistor, and whose source is coupled to the source of the second PMOS transistor.

33. The analog switch of claim 28, further comprising a third switch that drives the second PMOS transistor in an ON state when the control signal is activating the first PMOS transistor in an OFF state.

34. The analog switch of claim 33, wherein the third switch comprises a NMOS transistor whose gate receives the control signal, whose drain is connected to a negative supply, and whose source is coupled to the gate of the second PMOS transistor.

35. The analog switch of claim 28, further comprising a fourth switch that couples the signal received at the input terminal to the substrate of the first PMOS transistor when the first PMOS transistor is being driven to an ON state.
